(19) United States
(12) Patent Application Publication
(10) Pub. No.: US 2024/0122072 A1
(43) Pub. Date: Apr. 11, 2024

(54) THERMOELECTRIC CONVERSION MATERIAL, THERMOELECTRIC CONVERSION ELEMENT, THERMOELECTRIC CONVERSION MODULE, POWER GENERATION METHOD, AND HEAT TRANSFER METHOD

(71) Applicant: Panasonic Intellectual Property Management Co., Ltd., Osaka (JP)

(72) Inventors: RYOSUKE YAMAMURA, Osaka (JP); HIROMASA TAMAKI, Osaka (JP)

(21) Appl. No.: 18/542,606

(22) Filed: Dec. 16, 2023

Related U.S. Application Data
(63) Continuation of application No. PCT/JP2022/020875, filed on May 19, 2022.

(30) Foreign Application Priority Data
Jul. 5, 2021 (JP) 2021-111416

(51) Int. Cl. H10N 10/853; C22C 23/00

(52) U.S. Cl. CPC H10N 10/853; C22C 23/00

(57) ABSTRACT

The thermoelectric conversion material of the present disclosure has a composition represented by Mg_{3-a-b}AₐCa_{b}Sb₂₋ₓBiₓ. A includes at least one selected from the group consisting of Ag, Na, and Li, and 0<a≤0.035 is satisfied. The degree of c-axis orientation p of the thermoelectric conversion material and its composition satisfy, for example, the following condition. Condition (1): 0<b≤0.25, 0≤x<1.5, and 0.91<p≤1.

### BACKGROUND

### 1. Technical Field

The present disclosure relates to a thermoelectric conversion material, a thermoelectric conversion element, a thermoelectric conversion module, an electric power generation method, and a heat transfer method.

### 2. Description of the Related Art

Thermoelectric conversion materials containing Mg are previously known in the art. For example, Y. Fu et al. “Simultaneous improvement of power factor and thermal conductivity via Ag doping in p-type Mg₃Sb₂ thermoelectric materials,” Journal of Materials Chemistry A, Vol. 5, pp. 4932-4939 (2017) [DOI: 10.1039/c6ta08316a] (which is hereinafter referred to as NPL 1) discloses a polycrystalline thermoelectric conversion material represented by the chemical formula Mg₃₋ₓAgₓSb₂ and a method for producing the thermoelectric conversion material. In this chemical formula, the value of x is greater than or equal to 0 and less than or equal to 0.025.

X. Li et al., “Anisotropic electronic transport properties of Ag-doped Mg₃Sb₂ crystal prepared by directional solidification,” Journal of Applied Physics, 127, Vol. 127, pp. 195104 (2020) [DOI: 1 0.1063/5.0006340] (which is hereinafter referred to as NPL 2) discloses a monocrystalline thermoelectric conversion material represented by the chemical formula Mg₃₋ₓAgₓSb₂ and a method for producing the thermoelectric conversion material. In this chemical formula, the value of x is greater than or equal to 0 and less than or equal to 0.035.

F. Meng et al., “Anisotropic thermoelectric figure-of-merit in Mg₃Sb₂,” Materials Today Physics, Vol. 13, 100217 (2020) [DOI: 10.1016/j.mtphys.2020.100217] (which is hereinafter referred to as NPL 3) discloses analysis using computational estimation of the thermoelectric characteristics, in the c-axis direction and the a-axis or b-axis direction, of a material having a composition represented by the chemical formula Mg₃Sb₂.

S. Song et al., “Study on anisotropy of n-type Mg₃Sb₂-based thermoelectric materials,” APPLIED PHYSICS LETTERS, Vol. 12, pp. 092103 (2018) [DOI: 10.1063/1.5000053] (which is hereinafter referred to as NPL 4) discloses an oriented polycrystalline thermoelectric conversion material represented by the chemical formula Mg_{3.1}Nb_{0.1}Sb_{1.5}Bi_{0.49}Te_{0.01} and a method for producing the thermoelectric conversion material.

J. Shuai et. Al., “Thermoelectric properties of Na-doped Zintl compound: Mg₃₋ₓNaₓSb₂,” Acta Materialia, Vol. 93, pp. 187-193(2015) [DOI: 10.1016/j.actamat.2015.04.023] (which is hereinafter referred to as NPL 5) discloses a polycrystalline thermoelectric conversion material represented by the chemical formula Mg₃₋ₓNaₓSb₂ and a method for producing the thermoelectric conversion material. In this chemical formula, the value of x is greater than or equal to 0 and less than or equal to 0.025.

H. Wang et al., “Enhanced thermoelectric performance in p-type Mg₃Sb₂ via lithium doping,” Chinese Physics B, Vol. 27, 04721 2 (2018) [DOI: 10.1088/1674-1056/27/4/047212] (which is hereinafter referred to as NPL 6) discloses a polycrystalline thermoelectric conversion material represented by the chemical formula Mg₃₋ₓLiₓSb₂ and a method for producing the thermoelectric conversion material. In this chemical formula, the value of x is greater than or equal to 0 and less than or equal to 0.02.

W. Peng et al., “Limits of Cation Solubility in AMg₂Sb₂ (A=Mg, Ca, Sr, Ba) Alloys,” Materials, Vol. 12, pp. 586 (2018) [DOI: 10.3390/ma12040586] (which is hereinafter referred to as NPL 7) discloses a polycrystalline thermoelectric conversion material represented by the chemical formula Mg₃₋ₓCaₓSb₂ and a method for producing the thermoelectric conversion material. In this chemical formula, the value of x is greater than or equal to 0 and less than or equal to 1.0.

J. Xin et al., “Growth and transport properties of Mg₃X₂ (X═Sb, Bi) single crystals,” Materials Today Physics, Vol. 7, pp. 61-68 (2018) [DOI: 10.1016/j.mtphys.2018.11.004] (which is hereinafter referred to as NPL 8) discloses a monocrystalline thermoelectric conversion material represented by the chemical formula Mg₃X₂ (X═Sb, Bi) and a method for producing the thermoelectric conversion material.

S. Kim et. al., “Thermoelectric properties of Mg₃Sb₂₋ₓBiₓ single crystals grown by Bridgman method,” Materials Research Express, Vol. 2, 055903 (2015) [DOI: 10.1088/2053-1591/2/5/055903] (which is hereinafter referred to as NPL 9) discloses a monocrystalline thermoelectric conversion material represented by the chemical formula Mg₃Sb₂₋ₓBi x and a method for producing the thermoelectric conversion material. In this chemical formula, the value of x is greater than or equal to 0 and less than or equal to 2.0.

X. Li et al., “Influence of growth rate and orientation on thermoelectric properties in Mg₃Sb₂ crystal,” Journal of Materials Science: Materials in Electronics, Vol. 31, pp. 9773-9782 (2020) [DOI: 10.1007/s10854-020-03522-4] (which is hereinafter referred to as NPL 10) discloses a monocrystalline thermoelectric conversion material prepared by doping a material represented by the chemical formula Mg₃Sb₂ with elemental Ag and a method for producing the thermoelectric conversion material.

S. Kim et. al, “Thermoelectric properties of Mn-doped Mg—Sb single crystals,” Journal of Materials Chemistry, Vol. 2, pp. 12311-12316 (2014) [DOI: 10.1039/c4ta02386b] (which is hereinafter referred to as NPL 11) discloses a monocrystalline thermoelectric conversion material represented by the chemical formula Mg₃₋ₓMnₓSb₂ and a method for producing the thermoelectric conversion material. In this chemical formula, the value of x is 0, 0.3, or 0.4.

### SUMMARY

One non-limiting and exemplary embodiment provides a novel thermoelectric conversion material.

The thermoelectric conversion material of the present disclosure has a composition represented by Mg_{3-a-b}AₐCa_{b}Sb₂₋ₓBiₓ, wherein, in the composition, A includes at least one selected from the group consisting of Ag, Na, and Li, and 0<a≤0.035 is satisfied, and wherein a degree of c-axis orientation p of the thermoelectric conversion material and the composition of the thermoelectric conversion material satisfy any one of the following conditions (1) to (8):

0<b≤0.25,0≤x<1.5, and 0.91<p≤1; condition (1):

0<b<0.125,1.5≤x<2.0, and 0.91<p≤1; condition (2):

0<b≤0.25,0<x<1.5, and 0.66<p≤0.91; condition (3):

0.05<b≤0.25,x=0, and 0.66<p≤0.91; condition (4):

0.05<b≤0.25,1.0≤x<1.5, and 0.28≤p≤0.66; condition (5):

0<b≤0.25,0.5<x<1.0, and 0.28≤p≤0.66; condition (6):

0.125<b≤0.25,0<x≤0.5, and 0.28≤p≤0.66; and condition (7):

0<b<0.125,0<x≤0.5, and 0.28≤p≤0.66. condition (8):

The present disclosure can provide a novel thermoelectric conversion material.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic illustration of a La₂O₃-type crystal structure;

FIG. 2 is a graph showing an example of the results of a simulation of the X-ray diffraction pattern of the La₂O₃-type crystal structure;

FIG. 3 is a schematic illustration of the La₂O₃-type crystal structure of the thermoelectric conversion material of the present disclosure;

FIG. 4A is a schematic illustration showing an example of the results of a simulation of the crystal grain distribution in polycrystalline Mg₃Sb₂;

FIG. 4B is a schematic illustration showing another example of the results of the simulation of the crystal grain distribution in polycrystalline Mg₃Sb₂;

FIG. 4C is a schematic illustration showing still another example of the results of the simulation of the crystal grain distribution in polycrystalline Mg₃Sb₂;

FIG. 5 is a graph showing the results of a simulation of the degree of c-axis orientation p and the electric conductivity in the Z axis direction in polycrystalline Mg₃Sb₂; and

FIG. 6 is a schematic illustration showing an example of the thermoelectric conversion module of the present disclosure.

### DETAILED DESCRIPTIONS

### Findings Underlying the Present Disclosure

The performance of a thermoelectric conversion material is represented by the thermoelectric figure of merit ZT. The thermoelectric figure of merit ZT is represented by ZT=S²σT/κ using the Seebeck coefficient S, the electric conductivity σ, the thermal conductivity κ, and the absolute temperature T. The thermal conductivity κ is represented by κ=κₑ+κₗₐₜ using the electron thermal conductivity κₑ and the lattice thermal conductivity κₗₐₜ.

NPL 1 discloses a polycrystalline p-type thermoelectric conversion material represented by the chemical formula Mg₃₋ₐAₐSb₂. In NPL 1, A in the chemical formula Mg₃₋ₐAₐSb₂ is Ag. Moreover, the value of a is greater than or equal to 0 and less than or equal to 0.025. Under these conditions, the thermoelectric figure of merit ZT of the polycrystalline p-type thermoelectric conversion material represented by the above chemical formula is 0.12 at 330 K and 0.32 at 573 K. These thermoelectric figures of merit ZT are higher than the thermoelectric figures of merit ZT when the chemical formula does not include A, i.e., the thermoelectric figures of merit ZT of a thermoelectric conversion material when the value of a in the chemical formula is 0.

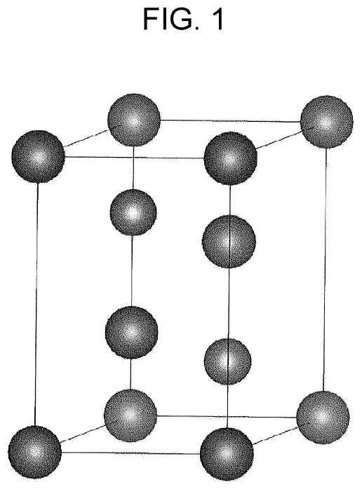

NPL 2 discloses a monocrystalline p-type thermoelectric conversion material represented by the chemical formula Mg₃₋ₐAₐSb₂. In NPL 2, A in the chemical formula Mg₃₋ₐAₐSb₂ is Ag. Moreover, the value of a is greater than or equal to 0 and less than or equal to 0.035. Under these conditions, the thermoelectric figure of merit ZT of the polycrystalline p-type thermoelectric conversion material represented by the above chemical formula is 0.15 at 330 K and 0.57 at 573 K as measured in the c-axis direction shown in FIG. 1. Specifically, these thermoelectric figures of merit ZT are higher than those of the polycrystalline material disclosed in NPL 1 and having the same composition.

NPL 3 discloses that the thermoelectric figure of merit ZT, in the c-axis direction, of monocrystalline Mg₃Sb₂ serving as a matrix is higher than the ZT in the a-axis or b-axis direction and the ZT of polycrystalline Mg₃Sb₂ and also discloses the mechanism of the high ZT based on quantum mechanics computations. However, no studies were made of the relation between the ZT, in the c-axis direction, of monocrystalline Mg₃Sb₂ serving as a matrix and containing an additional substituent element and the ZT of this monocrystalline Mg₃Sb₂ in the a-axis or b-axis direction and the relation between the ZT of this monocrystalline Mg₃Sb₂ in the c-axis direction and the ZT of polycrystalline Mg₃Sb₂. Moreover, no studies were made of the relation between the ZT of non-oriented polycrystalline Mg₃Sb₂ and the ZT of partially oriented polycrystalline Mg₃Sb₂ in which part of its crystal grains are oriented in specific directions and which differs from monocrystalline Mg₃Sb₂ and non-oriented polycrystalline Mg₃Sb₂ with its crystal grains oriented in random directions.

The inventors have developed a novel method that can predict the thermoelectric figure of merit ZT with high reliability. Specifically, the inventors have combined electronic state computations by a first principle computational method called the density functional theory (DFT) method and a prediction model for the thermoelectric figure of merit ZT developed by the inventors.

The inventors have computed the thermoelectric figure of merit ZT of a material including Mg₃(Sb,Bi)₂ as a matrix and having an unstudied composition by using a combination of the computation of the electronic state and the prediction model for the thermoelectric figure of merit ZT to thereby predict the ZT of the material. The inventors have found that, when the material is of the p-type and contains Ca within a synthesizable range, the ZT of the material in the c-axis direction is higher than the ZT, in the c-axis direction, of monocrystalline Mg₃(Sb,Bi)₂ serving as the matrix.

One example of a material intermediate between an unoriented polycrystalline material and a completely oriented monocrystalline material is a polycrystalline material partially oriented in the c-axis direction. The inventors have estimated the degree of c-axis orientation of a polycrystalline material using the X-ray diffraction method. The inventors have found from numerical simulations based on the finite element method that there is a specific relation between the degree of c-axis orientation of crystals and the electric conductivity σ and have established a novel method for computing the value of the ZT of a polycrystalline material having a certain degree of c-axis orientation. The inventors have newly found the thermoelectric conversion material of the present disclosure by using this method.

### Embodiments of the Present Disclosure

Embodiments of the present disclosure will be described with reference to the drawings.

The thermoelectric conversion material of the present disclosure has a composition represented by Mg_{3-a-b}AₐCa_{b}Sb₂₋ₓBiₓ. In this composition, A includes at least one selected from the group consisting of Ag, Na, and Li. For example, A includes only at least one selected from the group consisting of Ag, Na, and Li. Moreover, in this composition, 0<a≤0.035 is satisfied. The degree of c-axis orientation p of the thermoelectric conversion material and its composition satisfy any one of the following conditions (1) to (8). The degree of c-axis orientation p of the thermoelectric conversion material can be determined by a method using an X-ray diffraction method, which will be described later. When the thermoelectric conversion material satisfies any of these conditions, the ZT tends to be high.

0<b≤0.25,0≤x<1.5, and 0.91<p≤1 Condition (1):

0<b<0.125,1.5≤x<2.0, and 0.91<p≤1 Condition (2):

0<b≤0.25,0<x<1.5, and 0.66<p≤0.91 Condition (3):

0.05<b≤0.25,x=0, and 0.66<p≤0.91 Condition (4):

0.05<b≤0.25,1.0<x<1.5, and 0.28≤p≤0.66 Condition (5):

0<b≤0.25,0.5<x<1.0, and 0.28≤p≤0.66 Condition (6):

0.125<b≤0.25,0<x≤0.5, and 0.28≤p≤0.66 Condition (7):

0<b<0.125,0<x≤0.5, and 0.28≤p≤0.66 Condition (8):

The thermoelectric conversion material of the present disclosure has, for example, a La₂O₃-type crystal structure. In this case, the thermoelectric conversion material can more easily exhibit a high ZT.

The ZT of the thermoelectric conversion material at 330 K is not limited to a specific value. Preferably, the ZT of the thermoelectric conversion material at 330 K satisfies ZT>0.150. As described above, the thermoelectric conversion material of the present disclosure can exhibit a high ZT at 330 K.

The ZT of the thermoelectric conversion material at 573 K is not limited to a specific value. Preferably, the ZT of the thermoelectric conversion material at 573 K satisfies ZT>0.577. As described above, the thermoelectric conversion material of the present disclosure can exhibit a high ZT at 573 K.

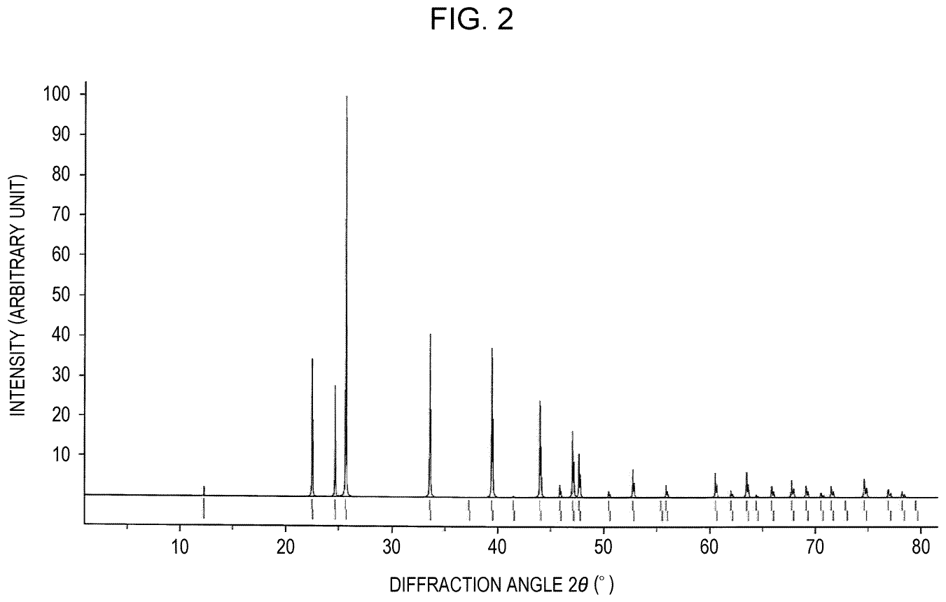

FIG. 1 schematically shows the La₂O₃-type crystal structure. It is stated in, for example, NPL 1 and NPL 2 that a material including Mg₃(Sb,Bi)₂ as a matrix can have the La₂O₃-type crystal structure which belongs to a space group P-3m1, or a CaAl₂Si₂-type crystal structure which belongs to the space group P-3m1. (Sb,Bi) means that at least one selected from the group consisting of Sb and Bi is contained. FIG. 2 shows an example of the results of a simulation of the X-ray diffraction pattern of polycrystalline Mg₃(Sb,Bi)₂ having the La₂O₃-type crystal structure. In the simulation results, the lattice constant in the a-axis direction is 4.57 angstroms and the lattice constant in the b-axis direction is 4.57 angstroms. The lattice constant in the c-axis direction is 7.23 angstroms. Software VESTA available from https://jp-minerals.org/vesta/jp/download.html was used to obtain the simulation results shown in FIG. 2. In FIG. 2, auxiliary lines indicating values of diffraction angles corresponding to the peaks in the X-ray diffraction pattern are provided between the X-ray diffraction pattern and the horizontal axis.

Whether the thermoelectric conversion material has the La₂O₃-type crystal structure can be determined by checking the presence of diffraction peaks that characterize the La₂O₃-type crystal structure using the X-ray diffraction method.

The thermoelectric conversion material of the present disclosure may be a monocrystal or a polycrystal having a prescribed degree of c-axis orientation p.

FIG. 3 schematically shows the La₂O₃-type crystal structure of the thermoelectric conversion material of the present disclosure. In this crystal structure, part of Mg sites C1 may be substituted with at least one element selected from the group consisting of Ag, Li, Na, and Ca. This crystal structure includes sites C2 occupied by elemental Mg. This crystal structure further includes sites C3 occupied by at least one element selected from the group consisting of Sb and Bi.

When the crystal structure of the thermoelectric conversion material is modified by the elemental substitution described above, the lattice constants of the La₂O₃-type crystal structure are changed. Therefore, the intensity peaks in the X-ray diffraction pattern of the thermoelectric conversion material of the present disclosure are shifted from the intensity peaks in the X-ray diffraction pattern of Mg₃(Sb,Bi)₂ shown in FIG. 2. The shift of the intensity peaks in the X-ray diffraction pattern is due to the change in the lattice constants of the crystal structure. When the lattice constants of the crystal structure increase, the intensity peaks in the X-ray diffraction pattern are shifted toward the low-angle side. When the lattice constants of the crystal structure decrease, the intensity peaks in the X-ray diffraction pattern are shifted toward the large-angle side.

The intensity ratios of the peaks in the X-ray diffraction pattern of the thermoelectric conversion material of the present disclosure may be changed depending on the degree of c-axis orientation p of the thermoelectric conversion material. When the degree of c-axis orientation p of the thermoelectric conversion material is larger than the degree of c-axis orientation p of an unoriented polycrystalline material, the intensity of a diffraction peak from the (001) plane is higher than the intensities of the other diffraction peaks. When the degree of c-axis orientation p of the thermoelectric conversion material is lower than the degree of c-axis orientation p of the unoriented polycrystalline material, the intensity of the diffraction peak from the (001) plane is lower than the intensities of the other diffraction peaks.

The thermoelectric conversion material has the above-described composition containing Ca. In this case, the ZT in the c-axis direction when the thermoelectric conversion material is a monocrystal tends to be higher than the ZT of a material including Mg₃(Sb,Bi)₂ as a matrix but containing no Ca. Moreover, the ZT when the thermoelectric conversion material is a polycrystal and has a prescribed degree of c-axis orientation p tends to be higher than the ZT of the material including Mg₃(Sb,Bi)₂ as a matrix but containing no Ca. In the thermoelectric conversion material of the present disclosure, part of Ca may be substituted with another element such as Yb.

The thermoelectric conversion material having the composition described above is stable and can be present as a monocrystalline material. Alternatively, the thermoelectric conversion material having the composition described above may be present as a polycrystalline material that does not include a plurality of crystal phases formed therein but includes crystal grains of one crystal phase and that has a prescribed degree of c-axis orientation p. In the composition described above, a, b, and x satisfy the conditions corresponding to the stable composition range of Mg_{3-a-b}AₐCa_{b}Sb₂₋ₓBiₓ. This stable composition range is a composition range in which only crystals having a composition of Mg_{3-a-b}AₐCa_{b}Sb₂₋ₓBiₓ can be present. In other words, the stable composition range means a composition range in which Mg_{3-a-b}AₐCa_{b}Sb₂₋ₓBiₓ can stably form a solid solution. When the composition is outside the stable composition range, crystal phases having compositions other than the composition Mg_{3-a-b}AₐCa_{b}Sb₂₋ₓBiₓ precipitate in addition to the crystals having the composition Mg_{3-a-b}AₐCa_{b}Sb₂₋ₓBiₓ, so that a material including only crystals having the composition Mg_{3-a-b}AₐCa_{b}Sb₂₋ₓBiₓ may not be obtained. In other words, when the composition is outside the stable composition range, a solid solution may not be formed stably.

The stable composition range can be determined, for example, by referring to the non-patent literature described above. According to NPL 2, it is understood that, when A in the above composition is Ag, the range of 0≤a≤0.035 can be the stable composition range. According to NPL 5, it is understood that, when A in the above composition is Na, the range of 0.0≤a≤0.025 can be the stable composition range for a. According to NPL 6, it is understood that, when A in the above composition is Li, the range of 0.0≤a≤0.02 can be the stable composition range. According to NPL 7, it is understood that the range of 0.0≤b≤1.0 in the above composition can be the stable composition range. According to NPL 8 and NPL 9, it is understood that the range of 0.0≤x≤2.0 can be the stable composition range for x.

One known indicator for quantifying the degrees of orientation in the c-axis direction of synthesized monocrystalline and polycrystalline materials is the Lotgering method in which the degree of orientation in one axial direction is estimated by an X-ray diffraction method. The inventors have found a method for estimating the c-axis orientation state and the electric conduction characteristics from integrated intensities of X-ray diffraction peaks using the Lotgering method. The details of the method will be described below.

In the Lotgering method, the degree of orientation p in the c-axis direction of a crystalline material is represented by the following formula (1).

p=Σ₀₀ₗI₀₀ₗ/ΣₕₖₗIₕₖₗ (1)

In formula (1), Thu is the relative intensity of a diffraction peak from the (hkl) plane. The value of p is in the range of 0≤p≤1 by definition. When p of a monocrystal along the a-axis or the b-axis is measured, p=0 is obtained. When p of a Mg₃Sb₂-based polycrystalline material not oriented in any direction is measured, p=0.07 is obtained. When p of a monocrystal along the c-axis is measured, p=1 is obtained. Specifically, an oriented polycrystalline material with p=0 is a material in which the a-axes or b-axes of the crystals are completely oriented. An oriented polycrystalline material with p=1 is a material in which the c-axes of the crystals are completely oriented. Therefore, monocrystalline materials and oriented polycrystalline materials can be evaluated using one variable p in a unified manner According to the conditions (1) to (8) described above, the degree of c-axis orientation p of the thermoelectric conversion material of the present disclosure falls within the range of greater than or equal to 0.07 and less than or equal to 1 and is greater than or equal to 0.28 and less than or equal to 1. When p is greater than or equal to 0.28, it is understood that the c-axes of about 50% or more of the crystal grains on the basis of the number of crystal grains are oriented.

From the viewpoint of obtaining high thermoelectric conversion performance, the degree of c-axis orientation p of the thermoelectric conversion material is preferably greater than or equal to 0.30, more preferably greater than or equal to 0.35, still more preferably greater than or equal to 0.40, and particularly preferably greater than or equal to 0.45.

For the purpose of evaluating the state of an incompletely oriented polycrystal, the inventors computed the electric conductivity of a polycrystalline material having a degree of c-axis orientation of p based on the finite element method. The angle between a plane with Miller indices (hkl) and the c axis is denoted by θₕₖₗ. Then the probability that a crystal grain is oriented in the θₕₖₗ direction is represented by a probability distribution function P(θₕₖₗ). Then the degree of orientation p in formula (1) can be represented by the following formula (2).

p=Σ₀₀ₗl′₀₀ₗ×P(θ₀₀ₗ)/Σₕₖₗl′ₕₖₗ×P(θₕₖₗ) (2)

In formula (2), I′ₕₖₗ is the relative intensity of the diffraction peak from the (hkl) plane in an unoriented polycrystalline material. In the finite element method, the function represented by the following formula (3) or (4) can be used to determine the orientations of the crystal grains of the polycrystalline material.

P(θₕₖₗ)=exp[−(cos(θₕₖₗ)−1)²/2Ω²] (3)

P(θₕₖₗ)=exp[−cos²(θₕₖₗ)/2Ω²] (4)

The selection between formula (3) and formula (4) and the value of Ω may be determined such that the value of p obtained from formula (1) is reproduced. The orientation of each crystal grain is determined according to the probability distribution function of formula (3) or (4). The electric conductivities in the x-, y-, and z-axis directions of the i-th voxel inside the oriented polycrystalline material can be defined as follows.

σᵢ=(σ_{x,i},σ_{y,i},σ_{z,i}) (5)

σ_{x,i}=(σ_{c}(1−z²)+σ_{ab}z²)cos²φᵢ+σₐ sin²φᵢ (6)

σ_{y,i}=(σ_{c}(1−z²)+σ_{ab}z²)sin²φᵢ+σₐ cos²φᵢ (7)

σ_{z,i}=σ_{c}(1−z²)+σ_{ab}z² (8)

z=cos θᵢ (9)

σ_{ab} is the electric conductivity of a crystalline material in the a-axis or b-axis direction. σ_{c} is the electric conductivity of the crystalline material in the c-axis direction. θᵢ is the angle between the z-axis and the c-axis of a crystal grain located in the i-th voxel, and ϕᵢ is the angle between the z-axis and the a-axis or b-axis of the crystal grain located in the i-th voxel. Specifically, the a-axes or b-axes of all the crystal grains in a polycrystalline material with p=0 are completely oriented in the z direction. In a polycrystalline material with p=1, the c-axes of all the crystal grains are completely oriented in the z direction.

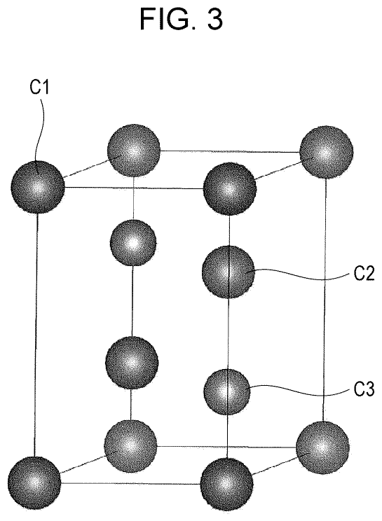

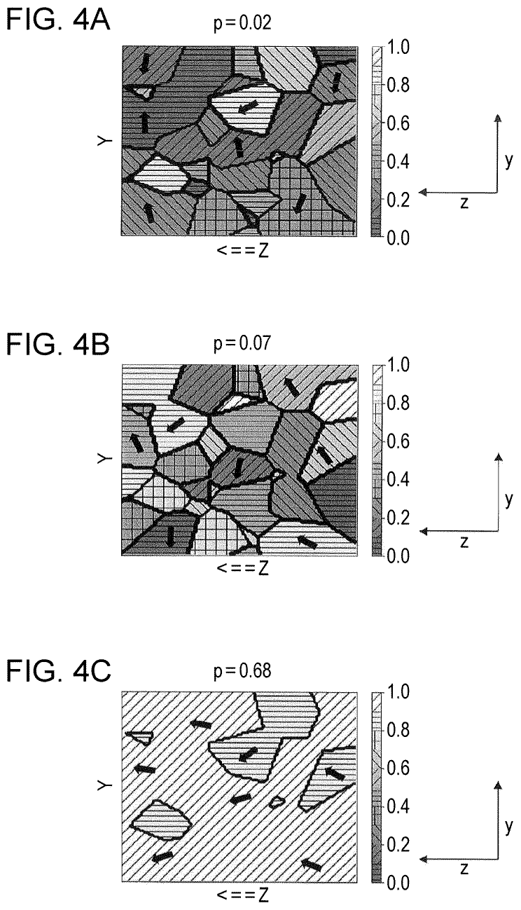

FIGS. 4A, 4B, and 4C show examples of the crystal grain distribution in the y-z planes of polycrystalline materials with p=0.02, p=0.07, and p=0.68, respectively. A color bar value represents the value of cos θᵢ in a crystal grain. An arrow inside a crystal grain indicates an example of the c-axis direction of the crystal grain based on θᵢ. The current density in the z direction and the average potential gradient are computed while the value of the degree of c-axis orientation p in the z direction is varied, and the electric conductivity of the oriented polycrystalline material in the z direction can thereby be determined. Specifically, as for the boundary conditions, the potential on a plane at z=0 is set to V=0, and the potential on a plane at an end along the z-axis is set to V=1. Under these boundary conditions, the current density in the i-th voxel can be represented by formula (10) below. The z-axis in the polycrystal used for the measurement is determined such that the degree of c-axis orientation p is maximized.

jᵢ=σᵢEᵢ (10)

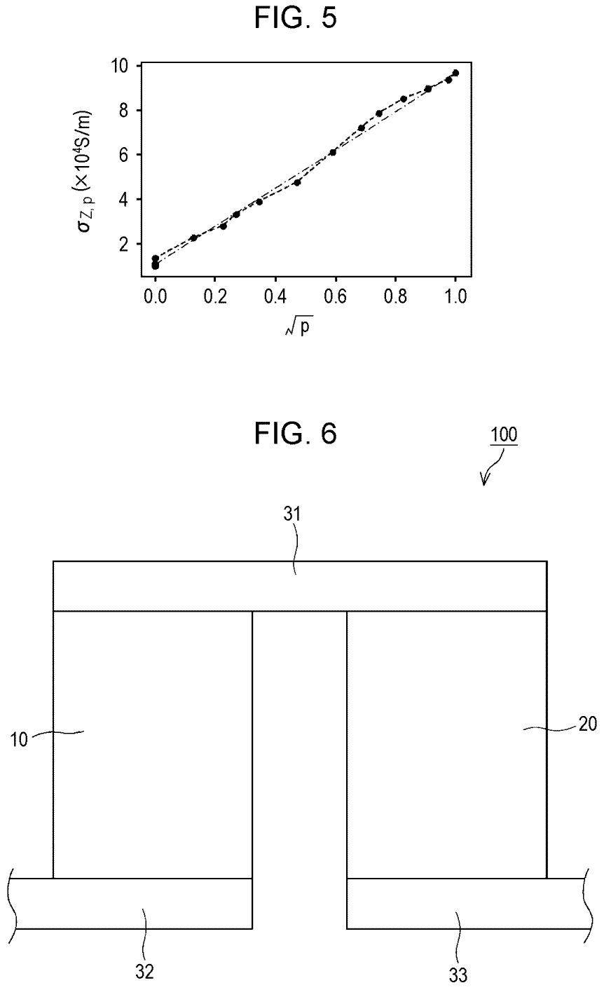

The simultaneous equations for the current density and potential gradient in each voxel are solved. The obtained current density and potential gradient in each voxel are used to determine the average current density and the average electric field gradient in the z direction on the x-y plane at the end along the z-axis, and the overall electric conductivity of the polycrystalline material in the z direction can thereby be computed. FIG. 5 shows the relation between the electric conductivity σ_{Z,p} in the z direction and the degree of c-axis orientation p that were obtained by the above computations for polycrystalline materials.

The value of σ_{ab} of p-type Mg₃Sb₂ is about 1×10⁴ S/m, and the value of σ_{c} of the p-type Mg₃Sb₂ is about 10×10⁴ S/m. The inventors have found that, as shown in FIG. 5, the degree of c-axis orientation p of a polycrystalline material in the z direction and its electric conductivity in the z direction have the relation represented by formula (11) below. In FIG. 5, a dash-dot straight line represents the relation of formula (11).

σ_{z,p}=σ_{ab}+(σ_{c}−σ_{ab})×p^{1/2} (11)

According to formula (11), σ_{Z,p} of an oriented polycrystalline material with p=0 accords with σ_{ab}, and σ_{Z,p} of an oriented polycrystalline material with p=1 accords with σ_{c}. In the present specification, the c-axis direction of a monocrystalline material coincides with the z-axis.

The thermoelectric conversion efficiency of a material can be evaluated by the thermoelectric figure of merit ZT that is intrinsic to the material. The ZT is defined by formulas (12) and (13) below. In formulas (12) and (13), S, σ, κₑ, and κₗₐₜ are the overall Seebeck coefficient of the material, the electric conductivity, the electron thermal conductivity, and the lattice thermal conductivity, respectively. T is the absolute temperature of the evaluation environment. The ZT can be predicted by using a combination of a Vienna Ab initio Simulation Package (VASP) code and a parabolic band model. As for the parabolic band model, refer to the description in Chapter 3 of H. J. Golds mid, “Introduction to Thermoelectricity,” Springer, 2010.

ZT=S²σT/κ (12)

κ=κₑ+κₗₐₜ (13)

Computational formulas for various characteristic values in the parabolic band model are shown in formulas (14) to (18). In formulas (14) to (18), the elementary charge e, the band effective mass m_{I,p}, the degree of degeneracy at the band edge N_{V}, the average longitudinal elastic constant Cₗ, the deformation potential Ξ, and the reduced Fermi energy η=E_{F}/k_{B}T are used.

S=−k_{B}/e×[F₂(η)/F₁(η)+η] (14)

σ_{p,z}=2e²hNᵥCₗ/3πm_{l,p}μ²×F₁(η) (15)

κₑ=σ_{p,z}×T×(k_{B}/e)²×[F₃(η)/F₁(η)−(F₂(η)/F₁(η))²] (16)

Fᵢ(η)=∫₀^{-∞}dx(−x)ⁱ×(−∂f₋(x,η)/∂x) (17)

f₋(x,η)=1−f₊(x,η),f₊(x,η)=1/(1+e^{x-η)} (18)

By substituting formulas (14) to (18) into formula (12), ZT is represented as follows.

ZT=[F₂(η)/F₁(η)−η]²×F₁(η)/[F₃(η)−F₂(η)²+1/β] (19)

β=αTNᵥ/m_{l,p}κₗₐₜ (20)

α=2k_{B}²hCₗ/3πΞ² (21)

According to formulas (19) to (21), the ZT of a thermoelectric conversion material can be determined based on the reduced Fermi energy η, α represented by the product of physical quantities, the absolute temperature T, the degree of degeneracy at the band edge N_{V}, the band effective mass m_{I,p} at a degree of c-axis orientation of p, and the lattice thermal conductivity κₗₐₜ.

The reduced Fermi energy can be uniquely determined from the value of the Seebeck coefficient. On the basis of the values of the Seebeck coefficients of monocrystalline Mg₃₋ₐAgₐSb₂ disclosed in NPL 2 in the c-axis and a-axis directions, it is understood that the dependence of the Seebeck coefficient on the degree of c-axis orientation p is small. Therefore, when A is Ag, the values of the reduced Fermi energy for different a values can be computed using the values of the Seebeck coefficient of monocrystalline Mg₃₋ₐAgₐSb₂ along the c-axis that are disclosed in NPL 2. When A is Na, the values of the reduced Fermi energy for different a values can be computed using the values of the Seebeck coefficient of polycrystalline Mg₃₋ₐNaₐSb₂ that are disclosed in NPL 5. When A is Li, the values of the reduced Fermi energy for different a values can be computed using the values of the Seebeck coefficient of polycrystalline Mg₃₋ₐLiₐSb₂ that are disclosed in NPL 6.

As for the product of various physical quantities that is represented by α, the value for the Mg₃(Sb,Bi)₂ crystalline material serving as a matrix under the conditions of a constant temperature and a constant carrier concentration can be used, and the influence of elemental substitution on the product is small. It can be assumed that the value of α does not change depending on the degree of c-axis orientation p. It can therefore be considered that the value of α is constant at the same temperature and the same carrier concentration. When A is Ag, the values of a can be determined such that the values of the ZT of monocrystalline Mg₃₋ₐAgₐSb₂ in the c-axis direction that are disclosed in NPL 2 for different temperatures and different carrier concentrations can be reproduced. When A is Na, the values of α can be determined such that the values of the ZT of polycrystalline Mg₃₋ₐNaₐSb₂ in the c-axis direction that are disclosed in NPL 5 for different temperatures and different carrier concentrations can be reproduced. When A is Li, the values of α can be determined such that the values of the ZT of polycrystalline Mg₃₋ₐLiₐSb₂ that are disclosed in NPL 6 for different temperatures and different carrier concentrations can be reproduced. The dependence of the electric conductivity σ_{Z,p} on the degree of c-axis orientation p may be due to the band effective mass m_{I,p}. Therefore, the band effective mass m_{I,p} can be obtained from a simulation of the electric conductivity of a polycrystalline material having a prescribed degree of c-axis orientation p using the finite element method and represented as follows.

1/m_{I,p}=1/mₖ_{ₐ}+(1/mₖ_{ₐ}−1/mₖ_{_{c}})×p^{1/2} (22)

In formula (22), mₖₐ and m_{kc} are effective masses along the a-axis and the c-axis, respectively. mₖₐ and m_{kc} together with the degree of degeneracy at the band edge N_{V} can be computed by the DFT method using the VASP code.

The lattice thermal conductivity κₗₐₜ can be determined by fitting based on the following formulas.

1/κₗₐₜ=1/κ_{lat,Sb-Bi}+Γ_{B}×b (23)

1/κ_{lat,Sb-Bi}=Δ_{Bi}+Γ_{Bi}×x(1−x) (24)

κ_{lat,Sb-Bi} is the lattice thermal conductivity of Mg₃(Sb,Bi)₂ serving as a matrix.

κ_{lat,Sb-Bi} is applicable to n-type Mg₃(Sb,Bi)₂ crystalline materials and also to p-type Mg₃(Sb,Bi)₂ crystalline materials so long as the matrix is Mg₃(Sb,Bi)₂. Δ_{Bi} and Γ_{Bi} can be determined such that the lattice thermal conductivity of an n-type Mg₃(Sb,Bi,Te)₂ polycrystalline material is reproduced. According to this determination, it is understood that Te, which is an n-type dopant, has the same influence on the lattice thermal conductivity as that of Ag, Na, and Li, which are p-type dopants, and therefore the influence of Te can be taken into consideration. The value of Γ_{B} can be determined such that the value of the lattice thermal conductivity determined by an experiment is reproduced.

By performing the computation according to the computational procedure described above, the thermoelectric figure of merit ZT of the thermoelectric conversion material of the present disclosure having a specific composition can be computed.

A method for producing the thermoelectric conversion material of the present disclosure is not limited to a specific method. A monocrystalline thermoelectric conversion material can be produced as follows, as disclosed in, for example, NPL 10. Elemental Mg, at least one single element selected from Sb and Bi, elemental Ca, and at least one single element selected from Ag, Na, and Li are weighed in a desired stoichiometric ratio. The weighed raw material elements are mixed and melted using a melting method. Then the obtained alloy ingot is placed in a carbon crucible, and a monocrystal can be produced in an argon gas atmosphere by a high temperature-gradient directional solidification method. A monocrystalline thermoelectric conversion material can thereby be obtained. Instead of the high temperature-gradient directional solidification method, a well-known monocrystalline material synthesis method for growing a crystal in one direction such as a Bridgman method disclosed in NPL 9 or a flux method disclosed in NPL 8 may be used.

A method for producing an oriented polycrystalline thermoelectric conversion material is not limited to a specific method. For example, an oriented polycrystalline thermoelectric conversion material can be produced using the high temperature-gradient directional solidification method described above. With the high temperature-gradient directional solidification method, an oriented polycrystalline thermoelectric conversion material with the degree of c-axis orientation p adjusted can be synthesized by adjusting the moving speed of the raw materials or a heat source. For example, when the moving speed of the raw materials or the heat source is reduced, the degree of c-axis orientation p tends to increase. An oriented polycrystalline thermoelectric conversion material may be produced, for example, by the following method described in NPL 4. Weighed single raw materials together with stainless steel balls are placed in a stainless steel container and sealed in the container in an argon atmosphere. Then a planetary ball mill method is used to subject the raw materials to pulverization mixing treatment. In this case, to prevent an alloy powder originating from the raw materials from adhering to the stainless steel container, stearic acid may be added. The thus-obtained alloy powder is placed in a graphite die, and a spark plasma sintering method in which the alloy powder is heated using a pulse current under pressure is performed to produce a bulk polycrystalline sintered body. Then the produced bulk polycrystalline sintered body is placed in a die lager than the graphite die, and the spark plasma sintering method is again performed under pressure. In this case, the pressure and temperature during the pressurization are set to be the same as or higher than the conditions for the previously performed spark plasma sintering method. By repeating this process a plurality of times, an oriented polycrystalline thermoelectric conversion material can be obtained. For example, by increasing the temperature or pressure in the spark plasma sintering method or increasing the number of repetitions of the spark plasma sintering method, the degree of c-axis orientation p of the thermoelectric conversion material can be easily increased. Instead of the spark plasma sintering method, a well-known sintering method such as a hot-press method may be used. Alternatively, an oriented polycrystalline thermoelectric conversion material may be produced by performing a heating step after the pulverization and mixing of the raw materials to prepare a precursor alloy powder and then sintering the alloy powder.

The thermoelectric conversion material of the present disclosure contains a plurality of elements. It is stated in NPL 11 that, even when Mn is included in the raw materials, a monocrystalline thermoelectric conversion material including Mg₃(Sb,Bi)₂ as a matrix can be produced by the same method as that described above. As described above, the thermoelectric conversion material of the present disclosure has a composition corresponding to the stable composition range. Therefore, the thermoelectric conversion material of the present disclosure can be stably produced by the production method described above.

A thermoelectric conversion element including the thermoelectric conversion material of the present disclosure can be provided. This thermoelectric conversion element can function, for example, as a p-type thermoelectric conversion element.

For example, a thermoelectric conversion module including a p-type thermoelectric conversion element including the thermoelectric conversion material of the present disclosure and an n-type thermoelectric conversion element can be provided. In this thermoelectric conversion module, the n-type thermoelectric conversion element is electrically connected to the p-type thermoelectric conversion element.

FIG. 6 shows an example of the thermoelectric conversion module according to the present embodiment. The thermoelectric conversion module 100 includes a p-type thermoelectric conversion element 10, an n-type thermoelectric conversion element 20, a first electrode 31, a second electrode 32, and a third electrode 33. The p-type thermoelectric conversion element 10 contains the thermoelectric conversion material of the present disclosure. The first electrode 31 electrically connects a first end of the p-type thermoelectric conversion element 10 to a first end of the n-type thermoelectric conversion element 20. The second electrode 32 is electrically connected to a second end of the p-type thermoelectric conversion element 10. The third electrode 33 is electrically connected to a second end of the n-type thermoelectric conversion element 20.

The thermoelectric conversion material contained in the n-type thermoelectric conversion element 20 is not limited to a specific material. The n-type thermoelectric conversion element 20 includes, for example, an n-type thermoelectric conversion material including a Mg₃(Sb,Bi)₂-based alloy as a main phase. In this case, the number ratio of Sb and Bi atoms contained in the p-type thermoelectric conversion material and the number ratio of Sb and Bi atoms contained in the n-type thermoelectric conversion material paired with the p-type thermoelectric conversion material in the thermoelectric conversion module 100 may be the same or different. When the number ratios of the atoms are the same, the difference in the thermal expansion coefficient between the p-type thermoelectric conversion material and the n-type thermoelectric conversion material tends to be small. Therefore, thermal stress generated in the thermoelectric conversion module 100 tends to be reduced. The n-type thermoelectric conversion element 20 may include a well-known thermoelectric conversion material or may be a well-known n-type thermoelectric conversion element.

The application of the thermoelectric conversion material of the present disclosure is not limited to a specific application. The thermoelectric conversion material of the present disclosure can be used for various applications including conventional thermoelectric conversion material applications.

An electric power generation method including, for example, the following steps (Ia) and (IIa) can be provided using the thermoelectric conversion material of the present disclosure.
(Ia) A temperature difference is generated in the thermoelectric conversion material.
(IIa) Electric power associated with thermoelectromotive force generated in the thermoelectric conversion material due to the temperature difference generated in (Ia) is extracted.

For example, electrodes are disposed at first and second ends of the thermoelectric conversion material of the present disclosure. A temperature difference is generated such that the first end has a higher temperature and the second end has a lower temperature, and then p-type carriers move from the first end of the thermoelectric conversion material to its second end, so that electric power is obtained.

A heat transfer method including, for example, the following steps (Ib) and (IIb) can be provided using the thermoelectric conversion material of the present disclosure.
(Ib) An electric current is caused to flow through the thermoelectric conversion material.
(IIa) Heat is transferred through the electric current caused to flow in (Ib).

For example, the heat is transferred from the first end of the thermoelectric conversion material to the second end. In this case, when the direction of the electric current is reversed, the direction of the heat transfer in the thermoelectric conversion material is also reversed. Therefore, the heat can be transferred from the second end of the thermoelectric conversion material to the first end.

### EXAMPLES

The validity of the computational model for the degree of c-axis orientation p in a crystalline material having the composition Mg_{3-a-b}AₐCa_{b}Sb₂₋ₓBiₓ was verified as follows. Specifically, comparisons were made with the experimental value of the ZT of monocrystalline Mg_{2.975}Ag_{0.025}Sb₂ including Mg₃(Sb,Bi)₂ as a matrix and disclosed in NPL 2 and with the experimental value of the ZT of polycrystalline Mg_{2.975}Ag_{0.025}Sb₂ disclosed in NPL 1. The degree of c-axis orientation p of the monocrystalline Mg_{2.975}Ag_{0.025}Sb₂ in NPL 2 is 1, and the degree of c-axis orientation p of the polycrystalline Mg_{2.975}Ag_{0.025}Sb₂ disclosed in NPL 1 is 0.07. The monocrystalline Mg_{2.975}Ag_{0.025}Sb₂ including Mg_{2.975}Ag_{0.025}Sb₂ as a matrix and disclosed in NPL 2 is used as Comparative Example 1-1, and the polycrystalline Mg_{2.975}Ag_{0.025}Sb₂ disclosed in NPL 1 is used as Comparative Example 2-1. Their ZT values are shown in Table 1. Moreover, the computational values of the ZT of the monocrystalline Mg_{2.975}Ag_{0.025}Sb₂ and the computational values of the ZT of polycrystalline Mg_{2.975}Ag_{0.025}Sb₂ having a degree of c-axis orientation p of 0.07 are shown in Table 1. These computational values were computed using the prediction model using the combination of the VASP code and the parabolic band model described above. In Table 1, the monocrystalline Mg_{2.975}Ag_{0.025}Sb₂ and the polycrystalline Mg_{2.975}Ag_{0.025}Sb₂ are shown as Comparative Example 1-2 and Comparative Example 2-2, respectively. The values of α in the prediction model were determined such that the experimental values of the ZT at different temperatures in Comparative Example 1-1 were reproduced. Table 1 shows the ZT values at 330 K and 573 K.

TABLE 1

| | Mg_{2.975}Ag_{0.025}Sb₂ | | |
|---|---|---|---|
| | Degree of c-axis | ZT | ZT |
| Composition | orientation p | (330 K) | (573 K) |
| Comparative Example 1-1 | 1 | 0.150 | 0.577 |
| (Experiment) | | | |
| Comparative Example 1-2 | 1 | 0.150 | 0.577 |
| (Computation) | | | |
| Comparative Example 2-1 | 0.07 | 0.088 | 0.296 |
| (Experiment) | | | |
| Comparative Example 2-2 | 0.07 | 0.066 | 0.271 |
| (Computation) | | | |

The computational values of the ZT in Comparative Examples 1-2 and 2-2 were equivalent to the experimental values of the ZT in Comparative Examples 1-1 and 2-1 that were experimentally evaluated using the actually synthesized materials. The measurement error of the ZT is generally about ±0.05. In consideration of the measurement error, when the computational ZT value is within ±0.1 of the experimental ZT value, the computational ZT value can be considered to be equivalent to the experimental ZT value. It was suggested that the prediction model for the ZT with the degree of c-axis orientation p taken into consideration was valid when the degree of c-axis orientation p is in the range of 0.07≤p≤1.0. This prediction model was used to study materials with Ca added thereto.

### Examples 1 to 32

A crystalline material having a composition of Mg_{2.975-b}Ag_{0.025}Ca_{b}Sb₂₋ₓBiₓ can be produced as follows, as disclosed, for example, in NPL 10. First, elemental Mg, elemental Sb, elemental Bi, elemental Ag, and elemental Ca used as raw materials are weighed in a desired compositional ratio and mixed, and the mixture is melted using the melting method. Then the obtained alloy ingot is placed in a carbon crucible, and the high temperature-gradient directional solidification method is performed in an argon atmosphere to produce a monocrystal. In this manner, the monocrystal having the composition Mg_{2.975-b}Ag_{0.025}Ca_{b}Sb₂₋ₓBiₓ including Mg₃(Sb,Bi)₂ as a matrix can be obtained. Moreover, a polycrystal having the composition Mg_{2.975-b}Ag_{0.025}Ca_{b}Sb₂₋ₓBiₓ can be obtained, for example, using the spark plasma sintering method.

Referring to FIG. 3, the crystalline material having the composition Mg_{2.975-b}Ag_{0.025}Ca_{b}Sb₂₋ₓBiₓ has defects formed by substituting part of Mg sites C1 with Ag and Ca. When such defects are present, lattice distortion may occur in the La₂O₃-type crystal structure. The lattice distortion causes a change in the lattice constants of at least part of the crystal. Therefore, it is predicted that the intensity peaks in the X-ray diffraction pattern of the thermoelectric conversion material having the above-described composition are shifted from the intensity peaks in the X-ray diffraction pattern of the polycrystalline Mg₃(Sb,Bi)₂ shown in FIG. 2. The shift of the peaks observed in the X-ray diffraction pattern is due to the change in the lattice constants. When the lattice constants increase, the peaks in the X-ray diffraction pattern are shifted toward the low-angle side. When the lattice constants decrease, the peaks in the X-ray diffraction pattern are shifted toward the high-angle side.

The intensity ratios of the peaks in the X-ray diffraction pattern are changed from the intensity ratios in the X-ray diffraction pattern of the polycrystalline Mg₃(Sb,Bi)₂ shown in FIG. 2 according to the value of the degree of c-axis orientation p of the crystals. As the value of the degree of c-axis orientation p increases from 0.07, the relative intensity of the diffraction peak from the (001) plane becomes higher than the intensities of the other diffraction peaks. As the value of the degree of c-axis orientation p decreases from 0.07, the relative intensity of the diffraction peak from the (001) plane becomes lower than the intensities of the other peaks.

In the crystalline material having the composition Mg_{2.975-b}Ag_{0.025}Ca_{b}Sb₂₋ₓBiₓ, A in the composition represented by Mg_{3-a-b}AₐCa_{b}Sb₂₋ₓBiₓ is Ag, and the value of a is 0.025. In the composition represented by Mg_{3-a-b}AₐCa_{b}Sb₂₋ₓBiₓ, when the condition 0.0≤a≤0.035 is satisfied, the composition is within the stable composition range. Referring to NPL 7, the value of b in this crystalline material satisfies the condition 0.0≤b≤1.0 and is within the stable composition range of 0.0≤b≤0.25. Referring to NPL 8 and NPL 9, the value of x in this crystalline material can satisfy the condition 0.0≤x≤2.0.

The thermoelectric figures of merit ZT of crystalline materials having the composition Mg_{2.975-b}Ag_{0.025}Ca_{b}Sb₂₋ₓBiₓ were computed using the same method as that for the computation of the thermoelectric figure of merit ZT of the crystalline material Mg_{2.975}Ag_{0.025}Sb₂. By preforming the computation according to the procedure using formulas (12) to (24) described above, the ZT, in the z-axis direction, of each crystalline material having the composition Mg_{2.975-b}Ag_{0.025}Ca_{b}Sb₂₋ₓBiₓ was computed with the influence of the degree of c-axis orientation p taken into consideration. In this computation, the values of α were determined such that the ZTs at different temperatures in the experiment in Comparative Example 1-1 were reproduced. The computational values of the ZT of Mg_{2.975-b}Ag_{0.025}Ca_{b}Sb₂₋ₓBiₓ at 330 K and 573 K are shown in Tables 2 and 3.

TABLE 2

| | Mg_{2.975-b}Ag_{0.025}Ca_{b}Sb₂₋ₓBiₓ | | | | |
|---|---|---|---|---|---|
| | | | | ZT | ZT |
| Composition | b | x | p | (330 K) | (573 K) |
| Comparative Example 1-2 | 0 | 0 | 1 | 0.150 | 0.577 |
| (Computation) | | | | | |
| Comparative Example 3 | 0.05 | 0.0 | 0.47 | 0.125 | 0.494 |
| Example 1 | 0.05 | 0.5 | 0.47 | 0.160 | 0.586 |
| Comparative Example 4 | 0.05 | 1.0 | 0.47 | 0.133 | 0.495 |
| Comparative Example 5 | 0.05 | 1.5 | 0.47 | 0.125 | 0.470 |
| Comparative Example 6 | 0.125 | 0.0 | 0.47 | 0.133 | 0.532 |
| Comparative Example 7 | 0.125 | 0.5 | 0.47 | 0.144 | 0.541 |
| Example 2 | 0.125 | 1.0 | 0.47 | 0.186 | 0.668 |
| Comparative Example 8 | 0.125 | 1.5 | 0.47 | 0.120 | 0.458 |
| Comparative Example 9 | 0.25 | 0.0 | 0.47 | 0.138 | 0.559 |
| Example 3 | 0.25 | 0.5 | 0.47 | 0.162 | 0.606 |
| Example 4 | 0.25 | 1.0 | 0.47 | 0.156 | 0.583 |
| Comparative Example 10 | 0.25 | 1.5 | 0.47 | 0.120 | 0.466 |
| Comparative Example 11 | 0.05 | 0.0 | 0.85 | 0.144 | 0.562 |
| Example 5 | 0.05 | 0.5 | 0.85 | 0.183 | 0.658 |
| Example 6 | 0.05 | 1.0 | 0.85 | 0.153 | 0.560 |
| Comparative Example 12 | 0.05 | 1.5 | 0.85 | 0.143 | 0.531 |
| Example 7 | 0.125 | 0.0 | 0.85 | 0.154 | 0.603 |
| Example 8 | 0.125 | 0.5 | 0.85 | 0.165 | 0.606 |
| Example 9 | 0.125 | 1.0 | 0.85 | 0.211 | 0.747 |
| Comparative Example 13 | 0.125 | 1.5 | 0.85 | 0.137 | 0.515 |
| Example 10 | 0.25 | 0.0 | 0.85 | 0.159 | 0.631 |
| Example 11 | 0.25 | 0.5 | 0.85 | 0.185 | 0.680 |
| Example 12 | 0.25 | 1.0 | 0.85 | 0.175 | 0.643 |
| Comparative Example 14 | 0.25 | 1.5 | 0.85 | 0.137 | 0.524 |

TABLE 3

| | Mg_{2.975-b}Ag_{0.025}Ca_{b}Sb₂₋ₓBiₓ | | | | |
|---|---|---|---|---|---|
| | | | | ZT | ZT |
| Composition | b | x | p | (330 K) | (573 K) |
| Example 13 | 0.05 | 0 | 0.97 | 0.153 | 0.592 |
| Example 14 | 0.05 | 0.5 | 0.97 | 0.194 | 0.690 |
| Example 15 | 0.05 | 1.0 | 0.97 | 0.162 | 0.589 |
| Example 16 | 0.05 | 1.5 | 0.97 | 0.152 | 0.558 |
| Comparative Example 15 | 0.05 | 2.0 | 0.97 | 0.062 | 0.261 |
| Example 17 | 0.125 | 0 | 0.97 | 0.163 | 0.635 |
| Example 18 | 0.125 | 0.5 | 0.97 | 0.174 | 0.635 |
| Example 19 | 0.125 | 1.0 | 0.97 | 0.223 | 0.783 |
| Comparative Example 16 | 0.125 | 1.5 | 0.97 | 0.145 | 0.541 |
| Example 20 | 0.25 | 0 | 0.97 | 0.168 | 0.663 |
| Example 21 | 0.25 | 0.5 | 0.97 | 0.195 | 0.713 |
| Example 22 | 0.25 | 1.0 | 0.97 | 0.183 | 0.671 |
| Comparative Example 17 | 0.25 | 1.5 | 0.97 | 0.145 | 0.550 |
| Example 23 | 0.05 | 0 | 1 | 0.157 | 0.605 |
| Example 24 | 0.05 | 0.5 | 1 | 0.198 | 0.704 |
| Example 25 | 0.05 | 1.0 | 1 | 0.166 | 0.601 |
| Example 26 | 0.05 | 1.5 | 1 | 0.155 | 0.569 |
| Comparative Example 18 | 0.05 | 2.0 | 1 | 0.062 | 0.266 |
| Example 27 | 0.125 | 0 | 1 | 0.167 | 0.648 |
| Example 28 | 0.125 | 0.5 | 1 | 0.178 | 0.647 |
| Example 29 | 0.125 | 1.0 | 1 | 0.228 | 0.797 |
| Comparative Example 19 | 0.125 | 1.5 | 1 | 0.148 | 0.552 |
| Example 30 | 0.25 | 0 | 1 | 0.172 | 0.676 |
| Example 31 | 0.25 | 0.5 | 1 | 0.199 | 0.727 |
| Example 32 | 0.25 | 1.0 | 1 | 0.187 | 0.682 |
| Comparative Example 20 | 0.25 | 1.5 | 1 | 0.149 | 0.562 |

As suggested in Tables 2 and 3, the ZTs of the crystalline materials according to Examples 1 to 32 having the composition Mg_{2.975-b}Ag_{0.025}Ca_{b}Sb₂₋ₓBiₓ are higher than the ZT in Comparative Example 1-2. It can be understood that, when a crystalline material having the above composition satisfies the specific conditions 0.05≤b≤0.25 and 0.0≤x≤1.5 and further satisfies the condition 0.47≤p≤1.0, a high ZT is obtained. In crystalline materials of the same composition with the same b and the same x, it can be understood that, as the degree of c-axis orientation p increases, the ZT in the z-axis direction increases monotonically. Specifically, when a crystalline material whose degree of c-axis orientation p is a specific value has a higher ZT than that in Comparative Example 1-2, a crystalline material having the same composition as the above crystalline material and having a higher degree of c-axis orientation p may have a higher ZT than that in Comparative Example 1-2. Moreover, among a plurality of crystalline materials having the same composition, the closer the value of the degree of c-axis orientation p to 1, the higher the ZT in the z-axis direction.

### Examples 33 to 36

A crystalline material having a composition of Mg_{2.875-a}AgₐCa_{0.125}SbBi can be produced as follows, as disclosed in, for example, NPL 10. First, elemental Mg, elemental Sb, elemental Bi, elemental Ag, and elemental Ca used as raw materials are weighed in a desired compositional ratio and mixed, and the mixture is melted using the melting method. Then the obtained alloy ingot is placed in a carbon crucible, and the high temperature-gradient directional solidification method is performed in an argon atmosphere to produce a monocrystalline material. In this manner, the monocrystalline material having the composition Mg_{2.875-a}AgₐCa_{0.125}SbBi including Mg₃(Sb,Bi)₂ as a matrix can be obtained. Moreover, a polycrystal having the composition Mg_{2.875-a}AgₐCa_{0.125}SbBi can be obtained, for example, using the spark plasma sintering method.

Referring to FIG. 3, the crystalline material having the composition Mg_{2.875-a}AgₐCa_{0.125}SbBi has defects formed by substituting part of Mg sites C1 with Ag and Ca. When such defects are present, lattice distortion may occur in the La₂O₃-type crystal structure. The lattice distortion causes a change in the lattice constants of at least part of the crystal. Therefore, it is predicted that the intensity peaks in the X-ray diffraction pattern of the thermoelectric conversion material having the above-described composition are shifted from the intensity peaks in the X-ray diffraction pattern of the polycrystalline Mg₃(Sb,Bi)₂ shown in FIG. 2. The shift of the peaks observed in the X-ray diffraction pattern is due to the change in the lattice constants. When the lattice constants increase, the peaks in the X-ray diffraction pattern are shifted toward the low-angle side. When the lattice constants decrease, the peaks in the X-ray diffraction pattern are shifted toward the high-angle side.

The intensity ratios of the peaks in the X-ray diffraction pattern are changed from the intensity ratios in the X-ray diffraction pattern of the polycrystalline Mg₃(Sb,Bi)₂ shown in FIG. 2 according to the value of the degree of c-axis orientation p of the crystals. As the value of the degree of c-axis orientation p increases from 0.07, the relative intensity of the diffraction peak from the (001) plane becomes higher than the intensities of the other diffraction peaks. As the value of the degree of c-axis orientation p decreases from 0.07, the relative intensity of the diffraction peak from the (001) plane becomes lower than the intensities of the other peaks.

In the crystalline material having the composition Mg_{2.875-a}AgₐCa_{0.125}SbBi, A in the composition represented by Mg_{3-a-b}AₐCa_{b}Sb₂₋ₓBiₓ is Ag. Referring to NPL 2, in this crystalline material, the condition 0.0≤a≤0.035 is satisfied. In this crystalline material, the value of b in Mg_{3-a-b}AₐCa_{b}Sb₂₋ₓBiₓ is 0.125. Referring to NPL 7, this b value is within the stable composition range of 0.0≤b≤0.25. Moreover, in this crystalline material, the value of x in Mg_{3-a-b}AₐCa_{b}Sb₂₋ₓBiₓ is 1. This value of x satisfies the condition 0.0≤x≤2.0 derived by referring to NPL 8 and NPL 9.

The experimental values of the ZT, in the c-axis direction, in Comparative Examples that use the monocrystalline Mg₃₋ₐAgₐSb₂ disclosed in NPL 2 with a=0.000, 0.005, 0.015, and 0.035 are shown in Table 4. In Table 4, Comparative Examples in which a=0.000, 0.005, 0.015, and 0.035 are shown as Comparative Examples 21-1, 22-1, 23-1, and 24-1, respectively. In Table 4, the experimental value of the ZT in the c-axis direction in Comparative Example 1-1 in which a in the monocrystalline Mg₃₋ₐAgₐSb₂ disclosed in NPL 2 is 0.025 is also shown. Moreover, the computational values of the ZT, in the c-axis direction, of crystalline materials having compositions corresponding to the compositions in these Comparative Examples are shown in Table 4 as Comparative Example 21-2, 22-2, 23-2, and 24-2. The computational values were obtained using the prediction model using the combination of the VASP code and the parabolic band model. The values of α at different a values were determined such that the experimental values for Comparative Examples 21-1, 22-1, 23-1, and 24-1 were reproduced.

TABLE 4

| | Composition | | | | | |
|---|---|---|---|---|---|---|
| | Mg_{3-a-b}AgₐCa_{b}Sb₂₋ₓBiₓ | | | | | |
| | | | | | ZT | ZT |
| | a | b | x | p | (330K) | (573K) |
| Comparative | 0.000 | 0 | 0 | 1 | 0.017 | 0.052 |
| Example 21-1 | | | | | | |
| (Experiment) | | | | | | |
| Comparative | 0.000 | 0 | 0 | 1 | 0.017 | 0.052 |
| Example 21-2 | | | | | | |
| (Computation) | | | | | | |
| Comparative | 0.005 | 0 | 0 | 1 | 0.119 | 0.419 |
| Example 22-1 | | | | | | |
| (Experiment) | | | | | | |
| Comparative | 0.005 | 0 | 0 | 1 | 0.119 | 0.419 |
| Example 22-2 | | | | | | |
| (Computation) | | | | | | |
| Comparative | 0.015 | 0 | 0 | 1 | 0.127 | 0.453 |
| Example 23-1 | | | | | | |
| (Experiment) | | | | | | |
| Comparative | 0.015 | 0 | 0 | 1 | 0.127 | 0.453 |
| Example 23-2 | | | | | | |
| (Computation) | | | | | | |
| Comparative | 0.025 | 0 | 0 | 1 | 0.150 | 0.577 |
| Example 1-1 | | | | | | |
| (Experiment) | | | | | | |
| Comparative | 0.025 | 0 | 0 | 1 | 0.150 | 0.577 |
| Example 1-2 | | | | | | |
| (Computation) | | | | | | |
| Comparative | 0.035 | 0 | 0 | 1 | 0.111 | 0.530 |
| Example 24-1 | | | | | | |
| (Experiment) | | | | | | |
| Comparative | 0.035 | 0 | 0 | 1 | 0.111 | 0.530 |
| Example 24-2 | | | | | | |
| (Computation) | | | | | | |

The values of the ZT, in the z-axis direction, of crystalline materials having a composition of Mg_{2.875-a}AgₐCa_{0.125}Sb₂₋ₓBiₓ with the influence of the degree of c-axis orientation p taken into consideration were computed using the same a values as those for the computation of the ZT in Comparative Example 21-2 etc. The computational values of the ZT of Mg_{2.875-a}AgₐCa_{0.125}Sb₂₋ₓBiₓ at 330 K and 573 K are shown in Table 5.

TABLE 5

| | Composition | | | | | |
|---|---|---|---|---|---|---|
| | Mg_{3-a-b}AgₐCa_{b}Sb₂₋ₓBiₓ | | | | | |
| | | | | | ZT | ZT |
| | a | b | x | p | (330K) | (573K) |
| Comparative | 0.000 | 0 | 0 | 1 | 0.017 | 0.052 |
| Example 21-2 | | | | | | |
| (Computation) | | | | | | |
| Comparative | 0.000 | 0.125 | 1.0 | 1 | 0.027 | 0.078 |
| Example 25 | | | | | | |
| Comparative | 0.005 | 0 | 0 | 1 | 0.119 | 0.419 |
| Example 22-2 | | | | | | |
| (Computation) | | | | | | |
| Example 33 | 0.005 | 0.125 | 1.0 | 1 | 0.183 | 0.596 |
| Comparative | 0.015 | 0 | 0 | 1 | 0.127 | 0.453 |
| Example 23-2 | | | | | | |
| (Computation) | | | | | | |
| Example 34 | 0.015 | 0.125 | 1.0 | 1 | 0.195 | 0.633 |
| Comparative | 0.025 | 0 | 0 | 1 | 0.150 | 0.577 |
| Example 1-2 | | | | | | |
| (Computation) | | | | | | |
| Example 35 | 0.025 | 0.125 | 1.0 | 1 | 0.228 | 0.797 |
| Comparative | 0.035 | 0 | 0 | 1 | 0.111 | 0.530 |
| Example 24-2 | | | | | | |
| (Computation) | | | | | | |
| Example 36 | 0.035 | 0.125 | 1.0 | 1 | 0.169 | 0.735 |

As shown in Table 5, in Examples 33, 34, 35, and 36 in which 0.005≤a≤0.035 is satisfied, the ZT values are larger than the ZT values in Comparative Examples 22-2, 23-2, 1-2, and 24-2, respectively, in each of which the value of α is the same as that in the corresponding Example.

### Examples 37 to 39

Even when A in the composition Mg_{3-a-b}AₐCa_{b}Sb₂₋ₓBiₓ is Na or Li, a crystalline material having p-type thermoelectric conversion characteristics can be obtained.

A crystalline material having a composition of Mg_{2.875-a}NaₐCa_{0.125}SbBi can be produced as follows, as disclosed in, for example, NPL 10. First, elemental Mg, elemental Sb, elemental Bi, elemental Na, and elemental Ca used as raw materials are weighed in a desired compositional ratio and mixed, and the mixture is melted using the melting method. Then the obtained alloy ingot is placed in a carbon crucible, and the high temperature-gradient directional solidification method is performed in an argon atmosphere to produce a monocrystal. In this manner, the monocrystal having the composition Mg_{2.875-a}NaₐCa_{0.125}SbBi including Mg₃(Sb,Bi)₂ as a matrix can be obtained. Moreover, a polycrystal having the composition Mg_{2.875-a}NaₐCa_{0.125}SbBi can be obtained, for example, using the spark plasma sintering method.

Referring to FIG. 3, the crystalline material having the composition Mg_{2.875-a}NaₐCa_{0.125}SbBi has defects formed by substituting part of Mg sites C1 with Na and Ca. These defects are the same as the defects in the crystalline material having the composition Mg_{2.875-a}AgₐCa_{0.125}SbBi described above. When the crystalline material has these defects, lattice distortion may occur in the La₂O₃-type crystal structure. The lattice distortion causes a change in the lattice constants of at least part of the crystal. Therefore, it is predicted that the intensity peaks in the X-ray diffraction pattern of the thermoelectric conversion material having the above-described composition are shifted from the intensity peaks in the X-ray diffraction pattern of the polycrystalline Mg₃(Sb,Bi)₂ shown in FIG. 2. The shift of the peaks observed in the X-ray diffraction pattern is due to the change in the lattice constants. When the lattice constants increase, the peaks in the X-ray diffraction pattern are shifted toward the low-angle side. When the lattice constants decrease, the peaks in the X-ray diffraction pattern are shifted toward the high-angle side.

The intensity ratios of the peaks in the X-ray diffraction pattern are changed from the intensity ratios in the X-ray diffraction pattern of the polycrystalline Mg₃(Sb,Bi)₂ shown in FIG. 2 according to the value of the degree of c-axis orientation p of the crystals. As the value of the degree of c-axis orientation p increases from 0.07, the relative intensity of the diffraction peak from the (001) plane becomes higher than the intensities of the other diffraction peaks. As the value of the degree of c-axis orientation p decreases from 0.07, the relative intensity of the diffraction peak from the (001) plane becomes lower than the intensities of the other peaks.

The crystalline material having the composition Mg_{2.875-a}NaₐCa_{0.125}SbBi is a material in which A in the composition represented by Mg_{3-a-b}AₐCa_{b}Sb₂₋ₓBiₓ is Na. Referring to NPL 6, this material can satisfy the condition 0.0≤a≤0.025. In this crystalline material, the value of b in the composition represented by Mg_{3-a-b}AₐCa_{b}Sb₂₋ₓBiₓ is 0.125. Referring to NPL 7, this b value is within the stable composition range of 0.0≤b≤0.25. Moreover, the value of x is 1. Referring to NPL 8 and NPL 9, this value of x satisfies the condition 0.0≤x≤2.0.

Experimental values of the ZT of polycrystalline Mg₃₋ₐNaₐSb₂ disclosed in NPL 5 with a=0.006, 0.0125, and 0.025 are shown in Table 6 as Comparative Examples 25-1, 26-1, and 27-1, respectively. Moreover, computational values of the ZT of the compositions in Comparative Examples 25-1, 26-1, and 27-1 are shown in Table 6 as Comparative Examples 25-2, 26-2, and 27-2. These computational values were obtained using the prediction model using the combination of the VASP code and the parabolic band model. Since the materials in Comparative Examples 25-1, 26-1, 27-1, 25-2, 26-2, and 27-2 are polycrystalline materials, the value of p was set to 0.07. The values of α for different a values were determined such that the experimental values of the ZT in Comparative Examples 25-1, 26-1, and 27-1 were reproduced.

TABLE 6

| | Composition | | | | | |
|---|---|---|---|---|---|---|
| | Mg_{3-a-b}NaₐCa_{b}Sb₂₋ₓBiₓ | | | | | |
| | | | | | ZT | ZT |
| | a | b | x | p | (330K) | (573K) |
| Comparative | 0.006 | 0 | 0 | 0.07 | 0.043 | 0.316 |
| Example 25-1 | | | | | | |
| (Experiment) | | | | | | |
| Comparative | 0.006 | 0 | 0 | 0.07 | 0.043 | 0.316 |
| Example 25-2 | | | | | | |
| (Computation) | | | | | | |
| Comparative | 0.0125 | 0 | 0 | 0.07 | 0.040 | 0.340 |
| Example 26-1 | | | | | | |
| (Experiment) | | | | | | |
| Comparative | 0.0125 | 0 | 0 | 0.07 | 0.040 | 0.340 |
| Example 26-2 | | | | | | |
| (Computation) | | | | | | |
| Comparative | 0.025 | 0 | 0 | 0.07 | 0.035 | 0.264 |
| Example 27-1 | | | | | | |
| (Experiment) | | | | | | |
| Comparative | 0.025 | 0 | 0 | 0.07 | 0.035 | 0.264 |
| Example 27-2 | | | | | | |
| (Computation) | | | | | | |

The values of the ZT, in the z-axis direction, of crystalline materials having a composition of Mg_{3-a-b}NaₐCa_{b}Sb₂₋ₓBiₓ with the influence of the degree of c-axis orientation p taken into consideration were computed using the same a values as those for the computation of the ZT in Comparative Example 25-2 etc. The computational values of the ZT of the crystalline materials having the composition Mg_{3-a-b}NaₐCa_{b}Sb₂₋ₓBiₓ and satisfying p=1 at 330 K and 573 K are shown in Table 7.

TABLE 7

| | Composition | | | | | |
|---|---|---|---|---|---|---|
| | Mg_{3-a-b}NaₐCa_{b}Sb₂₋ₓBiₓ | | | | | |
| | | | | | ZT | ZT |
| | a | b | x | p | (330K) | (573K) |
| Comparative | 0.006 | 0 | 0 | 0.07 | 0.043 | 0.316 |
| Example 25-2 | | | | | | |
| (Computation) | | | | | | |
| Example 37 | 0.006 | 0.125 | 1.0 | 1 | 0.143 | 0.822 |
| Comparative | 0.0125 | 0 | 0 | 0.07 | 0.040 | 0.340 |
| Example 26-2 | | | | | | |
| (Computation) | | | | | | |
| Example 38 | 0.0125 | 0.125 | 1.0 | 1 | 0.123 | 0.738 |
| Comparative | 0.025 | 0 | 0 | 0.07 | 0.035 | 0.264 |
| Example 27-2 | | | | | | |
| (Computation) | | | | | | |
| Example 39 | 0.025 | 0.125 | 1.0 | 1 | 0.099 | 0.542 |

As shown in Table 7, in Examples 37, 38, and 39 in which 0.006≤a≤0.025 is satisfied, the ZT values are larger than the ZT values in Comparative Examples 25-2, 26-2, and 27-2, respectively, in each of which the value of a is the same as that in the corresponding Example.

### Examples 40 to 42

A crystalline material having a composition of Mg_{2.875-a}LiₐCa_{0.125}SbBi can be produced as follows, as disclosed in, for example, NPL 10. First, elemental Mg, elemental Sb, elemental Bi, elemental Li, and elemental Ca used as raw materials are weighed in a desired compositional ratio and mixed, and the mixture is melted using the melting method. Then the obtained alloy ingot is placed in a carbon crucible, and the high temperature-gradient directional solidification method is performed in an argon atmosphere to produce a monocrystal. In this manner, the monocrystal having the composition Mg_{2.875-a}LiₐCa_{0.125}SbBi including Mg₃(Sb,Bi)₂ as a matrix can be obtained. Moreover, a polycrystal having the composition Mg_{2.875-a}LiₐCa_{0.125}SbBi can be obtained, for example, using the spark plasma sintering method.

Referring to FIG. 3, the crystalline material having the composition Mg_{2.875-a}LiₐCa_{0.125}SbBi has defects formed by substituting part of Mg sites C1 with Li and Ca. These defects are the same as the defects in the crystalline material having the composition Mg_{2.875-a}AgₐCa_{0.125}SbBi described above. When the crystalline material has these defects, lattice distortion may occur in the La₂O₃-type crystal structure. The lattice distortion causes a change in the lattice constants of at least part of the crystal. Therefore, it is predicted that the intensity peaks in the X-ray diffraction pattern of the thermoelectric conversion material having the above-described composition are shifted from the intensity peaks in the X-ray diffraction pattern of the polycrystalline Mg₃(Sb,Bi)₂ shown in FIG. 2. The shift of the peaks observed in the X-ray diffraction pattern is due to the change in the lattice constants. When the lattice constants increase, the peaks in the X-ray diffraction pattern are shifted toward the low-angle side. When the lattice constants decrease, the peaks in the X-ray diffraction pattern are shifted toward the high-angle side.

The intensity ratios of the peaks in the X-ray diffraction pattern are changed from the intensity ratios in the X-ray diffraction pattern of the polycrystalline Mg₃(Sb,Bi)₂ shown in FIG. 2 according to the value of the degree of c-axis orientation p of the crystals. As the value of the degree of c-axis orientation p increases from 0.07, the relative intensity of the diffraction peak from the (001) plane becomes higher than the intensities of the other diffraction peaks. As the value of the degree of c-axis orientation p decreases from 0.07, the relative intensity of the diffraction peak from the (001) plane becomes lower than the intensities of the other peaks.

The crystalline material having the composition Mg_{2.875-a}LiₐCa_{0.125}SbBi is a material in which A in the composition represented by Mg_{3-a-b}AₐCa_{b}Sb₂₋ₓBiₓ is Li. Referring to NPL 8, this crystalline material can satisfy the condition 0.0≤a≤0.025. In this crystalline material, the value of b in the composition represented by Mg_{3-a-b}AₐCa_{b}Sb₂₋ₓBiₓ is 0.125. Referring to NPL 7, this b value is within the stable composition range of 0.0≤b≤0.25. In this crystalline material, the value of x is 1. Referring to NPL 8 and NPL 9, this x value satisfies the condition 0.0≤x≤2.0.

Experimental values of the ZT of polycrystalline Mg₃₋ₐLiₐSb₂ disclosed in NPL 6 with a=0.005, 0.01, and 0.02 are shown in Table 8 as Comparative Examples 28-1, 29-1, and 30-1, respectively. Moreover, computational values of the ZT of the compositions in Comparative Examples 28-1, 29-1, and 30-1 are shown in Table 8 as Comparative Examples 28-2, 29-2, and 30-2, respectively. These computational values were obtained using the prediction model using the combination of the VASP code and the parabolic band model. Since the materials in Comparative Examples 28-1, 29-1, 30-1, 28-2, 29-2, and 30-2 are polycrystalline, the value of p was set to 0.07. The values of α for different a values were determined such that the experimental values of the ZT in Comparative Examples 28-1, 29-1, and 30-1 were reproduced.

TABLE 8

| | Composition | | | | | |
|---|---|---|---|---|---|---|
| | Mg_{3-a-b}LiₐCa_{b}Sb₂₋ₓBiₓ | | | | | |
| | | | | | ZT | ZT |
| | a | b | x | p | (330K) | (573K) |
| Comparative | 0.005 | 0 | 0 | 0.07 | 0.059 | 0.274 |
| Example 28-1 | | | | | | |
| (Experiment) | | | | | | |
| Comparative | 0.005 | 0 | 0 | 0.07 | 0.059 | 0.274 |
| Example 28-2 | | | | | | |
| (Computation) | | | | | | |
| Comparative | 0.01 | 0 | 0 | 0.07 | 0.099 | 0.336 |
| Example 29-1 | | | | | | |
| (Experiment) | | | | | | |
| Comparative | 0.01 | 0 | 0 | 0.07 | 0.099 | 0.336 |
| Example 29-2 | | | | | | |
| (Computation) | | | | | | |
| Comparative | 0.02 | 0 | 0 | 0.07 | 0.083 | 0.297 |
| Example 30-1 | | | | | | |
| (Experiment) | | | | | | |
| Comparative | 0.02 | 0 | 0 | 0.07 | 0.083 | 0.297 |
| Example 30-2 | | | | | | |
| (Computation) | | | | | | |

The values of the ZT, in the z-axis direction, of crystalline materials having a composition of Mg_{2.875-a}LiₐCa_{b}Sb₂₋ₓBiₓ with the influence of the degree of c-axis orientation p taken into consideration were computed using the same α values as those for the computation of the ZT in Comparative Example 28-2 etc. The computational values of the ZT of Mg_{2.875-a}LiₐCa_{0.125}Sb₂₋ₓBiₓ with p=1 at 330 K and 573 K are shown in Table 9.

TABLE 9

| | Composition | | | | | |
|---|---|---|---|---|---|---|
| | Mg_{3-a-b}LiₐCa_{b}Sb₂₋ₓBiₓ | | | | | |
| | | | | | ZT | ZT |
| | a | b | x | p | (330K) | (573K) |
| Comparative | 0.005 | 0 | 0 | 0.07 | 0.059 | 0.274 |
| Example 28-2 | | | | | | |
| (Computation) | | | | | | |
| Example 40 | 0.005 | 0.125 | 1.0 | 1 | 0.196 | 0.796 |
| Comparative | 0.01 | 0 | 0 | 0.07 | 0.099 | 0.336 |
| Example 29-2 | | | | | | |
| (Computation) | | | | | | |
| Example 41 | 0.01 | 0.125 | 1.0 | 1 | 0.286 | 0.896 |
| Comparative | 0.02 | 0 | 0 | 0.07 | 0.083 | 0.297 |
| Example 30-2 | | | | | | |
| (Computation) | | | | | | |
| Example 42 | 0.02 | 0.125 | 1.0 | 1 | 0.236 | 0.773 |

As shown in Table 9, in Examples 40, 41, and 42 in which 0.005≤a≤0.02 is satisfied, the ZT values are higher than the ZT values in Comparative Examples 28-2, 29-2, and 30-2, respectively, in each of which the value of α is the same as that in the corresponding Example.

The thermoelectric conversion material of the present disclosure can be used for a thermoelectric conversion device for converting thermal energy to electric energy.

What is claimed is:

1. A thermoelectric conversion material having a composition represented by Mg_{3-a-b}AₐCa_{b}Sb₂₋ₓBiₓ,
wherein, in the composition, A includes at least one selected from the group consisting of Ag, Na, and Li, and 0<a≤0.035 is satisfied, and
wherein a degree of c-axis orientation p of the thermoelectric conversion material and the composition of the thermoelectric conversion material satisfy any one of the following conditions (1) to (8):
0<b≤0.25,0≤x<1.5, and 0.91<p≤1; condition (1):
0<b<0.125,1.5≤x<2.0, and 0.91<p≤1; condition (2):
0<b≤0.25,0<x<1.5, and 0.66<p≤0.91; condition (3):
0.05<b≤0.25,x=0, and 0.66<p≤0.91; condition (4):
0.05<b≤0.25,1.0≤x<1.5, and 0.28<p≤0.66; condition (5):
0<b≤0.25,0.5<x<1.0, and 0.28≤p≤0.66; condition (6):
0.125<b≤0.25,0<x≤0.5, and 0.28≤p≤0.66; and condition (7):
0<b<0.125,0<x≤0.5, and 0.28≤p≤0.66. condition (8):

2. The thermoelectric conversion material according to claim 1, wherein the thermoelectric conversion material has a La₂O₃-type crystal structure.

3. The thermoelectric conversion material according to claim 1, wherein a thermoelectric figure of merit ZT of the thermoelectric conversion material at 330 K satisfies ZT>0.150.

4. The thermoelectric conversion material according to claim 1, wherein a thermoelectric figure of merit ZT of the thermoelectric conversion material at 573 K satisfies ZT>0.577.

5. A thermoelectric conversion element comprising the thermoelectric conversion material according to claim 1.

6. A thermoelectric conversion module comprising:
a p-type thermoelectric conversion element that is the thermoelectric conversion element according to claim 5; and
an n-type thermoelectric conversion element electrically connected to the p-type thermoelectric conversion element.

7. An electric power generation method comprising:
generating a temperature difference in the thermoelectric conversion material according to claim 1; and
extracting electric power associated with thermoelectromotive force generated in the thermoelectric conversion material due to the temperature difference.

8. A heat transfer method comprising:
causing an electric current to flow through the thermoelectric conversion material according to claim 1; and
transferring heat through the electric current.
